(19) United States
(12) Patent Application Publication
(10) Pub. No.: US 2025/0268091 A1
(43) Pub. Date: Aug. 21, 2025

(54) SEQUENTIAL DEPOSITION OF PEROVSKITES

(71) Applicant: OXFORD PHOTOVOLTAICS LIMITED, Yarnton Oxfordshire (GB)

(72) Inventors: Tom BAINES, Yarnton Oxfordshire (GB); Nicola BEAUMONT, Yarnton Oxfordshire (GB); James BEST, Yarnton Oxfordshire (GB); Laura Miranda PEREZ, Yarnton Oxfordshire (GB); Christopher CASE, Yarnton Oxfordshire (GB)

(21) Appl. No.: 18/845,287

(22) PCT Filed: Mar. 10, 2023
(86) PCT No.: PCT/GB2023/050577

§ 371 Date: Sep. 9, 2024

(30) Foreign Application Priority Data
Mar. 11, 2022 (GB) 2203452.4

(51) Int. Cl. H10K 71/16; H10K 30/40; H10K 30/57

(52) U.S. Cl. CPC H10K 71/164; H10K 30/40; H10K 30/57

(57) ABSTRACT

The invention provides a method for producing a perovskite material which comprises: i. The deposition of a first metal halide precursor; and ii. The deposition of a second metal halide precursor, wherein the halide component in the second metal halide precursor is different from that of the first metal halide precursor and the first and second metal halide precursors are deposited separately; and iii. The deposition of an inorganic halide precursor; and/or iv. The deposition of a first organic halide precursor; and v. Optionally, the deposition of a second organic halide precursor which is different from the first organic halide precursor; and vi. Optionally, the deposition of a third organic halide precursor which is different from the first and second organic halide precursors; to form the perovskite material which comprises a mixed halide; wherein steps i., ii., and iii., when present, are carried out by physical vapour deposition.

### FIELD OF THE INVENTION

The present invention relates to a sequential deposition process for making perovskite thin films comprising mixed halide components, wherein the final perovskite may comprise the typical ABX₃ structure or the double perovskite A₂BB′X₆ structure. The process comprises a layer-by-layer system comprising sequential deposition of the perovskite precursors. The process or parts of the process can be repeated numerous times to generate a perovskite film of a desired thickness and mitigate impurities in mixed halide perovskite structures.

### BACKGROUND OF THE INVENTION

Solar energy conversion is one of the most promising technologies to provide renewable energy. Currently, crystalline Si dominates the PV market with over a 95% share and a high performance of over 26% Power Conversion Efficiency (PCE). However, Si is currently close to reaching its maximum performance of around 29% PCE. In order to try and reduce costs even further, the efficiency will need to be improved beyond 30%. For example, a promising route to improving Si photovoltaic devices is to use tandem solar cells, often where Si may act as the bottom cell with a bandgap of 1.1-1.2 ev. However, to ensure such a tandem cell would be efficient, a suitable top cell needs to be found with an appropriately larger bandgap ev.

One class of photovoltaic materials that has attracted significant recent interest has been organic-inorganic halide perovskites. Materials of this type have a perovskite crystal structure with general formula ABX₃. Another type of perovskite crystal structure is the double perovskite formula A₂BB′X₆. These materials have been found to exhibit favourable and tuneable bandgaps from 1.1 to 2.5 eV, high absorption coefficients, and long diffusion lengths, rendering such compounds ideal as an absorber for single junction photovoltaic devices, and for top, middle,) and bottom cells in multijunction devices.

Accordingly, the described process and its corresponding perovskites are suitable for use in semiconductor devices such as photovoltaic devices, single junction solar cells or multi-junction solar cells, including perovskite-silicon tandem cells, all-perovskite tandem solar cells, perovskite-perovskite-silicon tandem cells, perovskite-CdTe tandem cells, perovskite-CuZnSnSSe tandem cells, perovskite-CuZnSnS tandem cells, and perovskite-ClGS tandem cells.

Such perovskites can be synthesised by a variety of techniques, ranging from solution processes, such as spin-coating and blade coating, to dry processes, such as vapour deposition processes, including thermal evaporation, chemical vapour deposition (CVD) and aerosol-assisted CVD, etc. Often wet process methods are employed for making complex multicomponent perovskite compositions, as dry processes tend to become more complex when further components are introduced into the perovskite structure. For example, in WO2018026326A1 complex 3D perovskites with improved crystallinity are synthesised by treating a halide perovskite solution with deuterium oxide.

However, dry processes present an advantageous method for producing perovskites, as they are generally more scalable and less damaging to pre-existing device layers than solution processes. In order for perovskites to be suitable for tandem applications, they need to be phase pure and produced by scalable deposition methods.

Previously, co-evaporation methods have been adopted to synthesise multicomponent perovskites, i.e. perovskites containing multiple halide, metal or organic ions in the structure. However, co-evaporation can prove a challenging and expensive technique to impart control. This is because a greater number of evaporation sources requires more monitoring of the deposition rates and respective temperatures, to ensure the desired final stoichiometry results. In particular, the deposition of the organic components can be particularly challenging, requiring more care and control, and will therefore have to be done using a different set-up to the inorganic components. Furthermore, often multi-deposition of inorganic layers results in the production of secondary phases and accordingly lower device performance. Conversely, sequential vapour deposition, whereby precursors can be deposited layer-by-layer in a stepwise fashion can be used. Although this process may require more steps, it involves an economical and straightforward process, which is often linear and which is useful for fabricating perovskite solar cells for in-line production with precisely defined layer thicknesses, and reproducible and phase pure layers, leading to higher quality and more uniform films.

Thus far in the art, sequential deposition has been used to synthesise ABX₃ and A₂BB′X₆ type perovskites and accordingly, shown great successes with the final materials. However, the ability to synthesise a complex multicomponent perovskite via sequential deposition has not yet been accomplished, particularly with reference to mixed halide perovskites.

Kam et al. (“Efficient Mixed-Cation Mixed-Halide Perovskite Solar Cells by All-Vacuum Sequential Deposition Using Metal Oxide Electron Transport Layer”, Solar RRL, Vol.3, 7, 1900050, 2019) combined sequential vapour deposition and co-evaporation to synthesise a multicomponent perovskite, MA_{0.56}FA_{0.44}Pbl_{2.67}Br_{0.33}. The process involved the pre-mixing of Pbl₂ and PbBr₂ salts to form a single mixed lead halide precursor and subsequently evaporating this compound onto a substrate. Following this, MAI and FAI were also pre-combined in a single evaporation source and sublimed on top of the existing mixed lead halide layer and then annealed in situ to ultimately form the mixed-cation mixed-halide perovskite. While this resulted in a high-quality, uniform, and single-crystal-thick perovskite film, the pre-mixing of Pbl₂ and PbBr₂ can present difficulties in fully controlling the stoichiometry.

Since the boiling point of Pbl₂ is higher than that of PbBr₂, Pbl₂ tends to be the dominant precursor in the crucible, meanwhile the bromine compound is preferentially evaporated. Thus, it is difficult to entirely manipulate the quantities of I:Br and assert control over the stoichiometry.

Further, US2020328077A1 discloses a vapour deposition method of forming a perovskite precursor comprising the deposition of one or more organic precursors, inorganic precursors, metal halide precursors and/or alkali halide precursors. The precursors may be vaporised together or individually but are ultimately deposited as one “constituent vapour”, meaning a mixture of all of the precursor vapours, to form the final perovskite film.

Hence, metal halide precursors are deposited together via one vapour mixture, presenting a similar challenge regarding stoichiometry control and the formation of poorly mixed phases. Guo et al. (“Sequential Deposition of High-Quality Photovoltaic Perovskite Layers via Scalable Printing Methods”, Advanced Functional Materials, Vol. 29, 24, 2019) performed a scalable sequential two-step deposition “blade-coating” approach to fabricate a MAPbl₃ perovskite thin film, whereby Pbl₂ is first deposited, excess solvent is removed by vacuum extraction, followed by a second deposition step of MAI and a final thermal annealing step. The method produced films with complete surface coverage, optimal crystallinity and ultimately led to devices showing appreciable PCEs of up to 16.71%. However, this technique has not been proven a working solution for the synthesis of complex multicomponent perovskites, particularly with respect to mixed halide components which, often inherently incur complex impurity phases.

This is usually because of the varying and complex precursor materials which have been used to make the mixed halide. In particular, where two organic precursors contain very different sized A cations with respect to each other, the likelihood of phase segregation is increased as the tolerance factor of the perovskite is more likely to stray from the ideal stabilised structure. For example, including larger cations (e.g. FA⁺) into a lattice comprised of smaller cations (e.g. Cs⁺) will incur lattice distortion of the perovskite to try and accommodate the larger cations, leading to impurities, side phases, and general instability. Thus, introducing multiple different components into a perovskite requires careful control of each parameter to ensure a stable structure. The present invention, however, offers a method to overcome the issues of depositing structurally complex materials together to form a stable and pure perovskite film.

Sequential evaporative methods have also been executed by Reinoso et al. (“Improvement Properties of Hybrid Halide Perovskite Thin Films Prepared by Sequential Evaporation for Planar Solar Cells”, Materials (Basel), 12(8), 1394, 2019) to synthesise FAPbl₃ and MAPbl₃ perovskite films. A high-vacuum scheme was adopted, using virtual instrumentation to enable electronic control of the temperature and deposition rates of two evaporation sources, with the objective of making highly uniform, crystalline and reproducible films. A two-step process is enforced, wherein firstly a crucible of Pbl₂ precursor is evaporated and deposits until a desired thickness is achieved. Secondly, MAI or FAI precursor is evaporated onto the Pbl₂ layer, followed by annealing in N₂ for 20 min at 100-140° C. Once again, although the method demonstrated the use of sequential deposition to produce single-phase films with optimised morphologies, only two steps are performed and the resulting perovskite is that of a simple single halide structure, consisting of few components. Thus, in view of Guo et al. and Reinoso et al., there remains a need to find a scalable method which can also be used to make complex perovskite and double perovskite structures.

A quasi-2D-3D hybrid perovskite light-emitting layer for use in LED devices was fabricated by Fu et al. (“Scalable All-Evaporation Fabrication of Efficient Light-Emitting Diodes with Hybrid 2D-3D Perovskite Nanostructures”, Advanced Functional Materials, Vol.30, 39, 2020), wherein a three-step layer-by-layer sequential deposition method was employed. The first step comprised vapour deposition of PbBr₂ on ITO, followed by the consecutive deposition of CsBr and butylammonium bromide (BABr), and a final annealing treatment to form the (BA)₂CSₙ₋₁PbₙBr₃ₙ₊₁ perovskite film of a desired thickness. A variety of ratios of BABr/(BABr+CsBr) were explored to control the material molecular structure, whereby if the ratio was 0, a 2D structure resulted, and if the ratio was 1, a 3D structure resulted. As such, quasi-2D-3D hybrid perovskites with mixed 2D and 3D phases were synthesised by manipulating this compositional ratio, along with annealing temperature and film thicknesses. Evidently, forming a single phase perovskite still presents a challenge.

Similarly, GB2577492A discloses a process of improving the crystallinity of 3D organic-inorganic metal halide perovskites by converting a 2D perovskite material into the desired 3D perovskite material. The process involves forming a layer of a 2D perovskite material onto a substrate rather than a typical perovskite precursor and subjecting said layer to a reaction step to convert the 2D perovskite material to a 3D perovskite analogue, wherein a variety of deposition methods may be employed, such as PVD, CVD and solution deposition. For example, (PEA)₂Pbl₄ may first be deposited, followed by FAI:FABr to achieve final 3D perovskite FAPbl₂Br.

Fu et al. provides the first sequential method for depositing perovskites comprising more than 3 components, namely a mixed organic-inorganic perovskite. However, none of the above prior art has achieved the vapour deposition synthesis of mixed-halide perovskites, especially those which comprise triple or quadruple cations. It is well-known that Pbl₂ and PbBr₂ do not intermix very well due to their different crystal structures, and often a poorly mixed film is formed, inhibiting perovskite formation. Accordingly, most sequential deposition research has focused on depositing layers which are structurally compatible and mix easily, leading to simple final perovskite systems. As seen with Kam et al., pre-treating Pbl₂ and PbBr₂ at high temperatures before performing co-evaporation was one way to attempt a single mixed halide phase, but presented stoichiometric and process control difficulties, inherent to the co-evaporation process. Currently, most mixed halide perovskites are therefore predominantly made using solution-deposition methods which are not always scalable, nor ideal for making highly uniform multi-component perovskites.

Furthermore, Ngqoloda et al. (“Mixed-halide perovskites solar cells through PblCl and PbCl₂ precursor films by low-pressure sequential chemical vapor deposition”, Solar Energy, Vol. 215, 179-188, 2021) carried out three-step sequential deposition to achieve the mixed lead halide perovskite film, MAPblₓCl₁₋ₓ. The steps comprised the successive deposition of PbCl₂ vapour, followed by Pbl₂ vapour (which cumulatively gave a PblCl film thickness of 143 nm), and a final deposition of the MAI vapour. It was further established that no Cl substitution by iodine was observed during the sequential deposition of the lead halide films, but a reaction took place to form a pure single lead chloride iodide phase (PblCl). Instead, substitution of Cl by iodine ions only occurred during the conversion to the perovskite phase. Nggoloda provides a chemical vapour deposition process (CVD), whereas the present invention discloses a physical (thermal) vapour deposition (PVD) process. However, it is well known that single A cation perovskite materials aren't complex structures. Thus, forming MAPblₓCl₁₋ₓ will not present many, if any, impurities in the first place. As more complex structures and additional components are introduced into the perovskite, undesirable impurity phases become more apparent. The present invention provides a means to synthesise structurally complex perovskites, meanwhile eliminate such impurities.

Further, it is well known in the art that CVD processes tend to require a more complex and fine-tuned set up such as a chamber for the initial vaporisation of the precursors and further gas delivery chamber. In contrast, thermal PVD is considered a more standardised industrial process, often requiring less demanding temperatures and conditions, whereby the precursors can be evaporated in their solid form. Thin films made with PVD tend to demonstrate superior resistance properties, such as to ablation, which is key for improving the longevity of a perovskite-based device.

A challenge with PVD however is forming complex, structurally stable and phase pure final films, especially when multiple different structured materials are deposited. The present claimed process thus provides a means to mitigate impurities in the final perovskite phase and deposit crystalline films via the preferred PVD process.

Furthermore, double perovskites are also a promising material for use as photoactive materials and have attracted more attention in recent years as an alternative to resolve some of the instability and lead-based toxicity encountered with typical hybrid perovskites. As with the standard perovskite structures, double perovskites films are mostly formed by solution processes. Recently, Wang et al. (“Vapor-Deposited Cs₂AgBiCl₆ Double Perovskite Films toward Highly Selective and Stable Ultraviolet Photodetector”, Advanced Science, Vol.7, 11, 2020) used sequential vapour deposition to fabricate high-quality Cs₂AgBiCl₆ double perovskite films with balanced stoichiometry, enhanced morphology, and highly oriented crystallinity with an indirect bandgap of 2.41 ev. The sequential vapour deposition technique involved deposition of CsCl, BiCl₃ and AgCl onto a prepared substrate layer-by-layer followed by annealing in N₂ environment, equating to one complete cycle of deposition. Wang reported that films of larger desired thickness could be achieved by merely repeating the deposition cycle. Similarly, Luo et al. (“Efficient and stable emission of warm-white light from lead-free halide double perovskites”, Nature, 563, 541-545, 2018) synthesised Bi-doped and Na-alloyed Cs₂AgₓNa₁₋ₓInCl₆ via hydrothermal synthesis and sequential thermal evaporation of CsCl, InCl₃, BiCl₃, NaCl and AgCl with a final annealing step. Though these methods resulted in a controlled and ideal stoichiometry, the synthesis of complex double perovskites comprising a) mixed halide components and b) mixed organic-inorganic components is yet to be accomplished. As with the standard perovskite structures, the compatibility of certain precursors can pose an issue for developing uniform and structurally complex films comprising many different ions.

As such, deposition of mixed halide double perovskites has presently only been realized via solution processing methods, as illustrated by Nath et al. (“Synthesis and Study of Different Properties of Single Halide and Mixed Halide Double Perovskites”, nanoGe conference, 23 Apr. 2020), which reported an antisolvent precipitation process. Chini et al. (“Lead-free, stable mixed halide double perovskites Cs₂AgBiBr₆ and Cs₂AgBiBr₆₋ₓClₓ—A detailed theoretical and experimental study”, Chemical Physics, Vol. 529, 2020) and Wu et al. (“Mixed-halide double perovskite Cs₂AgBiX₆ (X=Br, I) with tuneable optical properties via anion exchange”, ChemSusChem, 2021 October 20; 14 (20): 4507-4515) each provide a spin-coating method. Nath and Chini discuss the advantages of using mixed halide perovskites, namely the tunability of the absorption spectrum, structural stability, and bandgap malleability, particularly with increased Cl content. Meanwhile, Wu reported an anion exchange mechanism using volatile organic iodide salts. Naturally however, all of these solution processes suffer scalability issues and thus questionable industrial applicability.

Minimal research has been invested into synthesising double perovskites via dry process techniques, and even less so to form more intricate multicomponent structures by sequential deposition. Mixed halide or mixed organic-inorganic double perovskites have also not yet been fully explored in the art.

The present invention therefore intends to resolve typical dry processing issues experienced in the field by developing a simplified process, which is often linear, to fabricate homogeneous complex multicomponent perovskites and/or double perovskite layers of a desired thickness and exceptional quality and uniformity. Commonly in the field, the large number of precursors needed to synthesise a complex multicomponent mixed-halide perovskite containing has incited a preference for multi-source evaporation or solution-based techniques. However, the present unique sequential process entails high-temperature depositions and/or optional intermittent annealing, which induces a high level of molecular reorganisation, thereby yielding superior crystallinity and high-quality films, which naturally improves the device performance.

### SUMMARY OF THE INVENTION

According to a first aspect of the invention, there is provided a method as outlined in claim 1. Increasing the number of components (number of A and/or B cations, and/or X halides) in the ABX₃ perovskite formula brings advantages in terms of material/device performance and environmental stability. However, introducing multiple components into a perovskite film can often require very complex dry processes, whereby in either case, the stability and quality of the film is often compromised. Although viable through solution processes, these often experience issues with scale up and maintaining the film quality and device efficiency established at lab scale.

The present invention provides for the synthesis of a high-performing multicomponent perovskite via sequential deposition of each distinct precursor, such that complex films of a controlled thickness can be achieved on a step-by-step basis without the need for prior processing or simultaneous management of the multiple precursor sources. As such, a number of halide precursor compounds can be sequentially deposited to give a mixed-halide perovskite film. Consequently, the present claimed invention adopts a simple deposition process, which is often linear and thus is easily capable of industrial scale-up, (optionally wherein the process or parts of the process can be repeated) to produce a specific final stoichiometry and thickness. Further advantageously, most of the precursors suitable for the present invention are halide compounds which often naturally occur in the solid form and can be directly utilised in the claimed thermal PVD process.

Accordingly, the described process and its corresponding perovskites are suitable for use in semiconductor devices such as photovoltaic devices, single junction solar cells, or multi-junction solar cells including perovskite-silicon tandem cells, all-perovskite tandem solar cells, perovskite-perovskite-silicon, perovskite-CdTe tandem cells, perovskite-CuZnSnSSe tandem cells, perovskite-CuZnSnS tandem cells, and perovskite-ClGS tandem cells.

In the literature one can find the solution to synthesizing a multicomponent mixed-halide perovskite via various complex techniques. However, in many cases these solutions may present more opportunity for error in trying to monitor several precursors, or they simply won't lead to highly or homogeneous uniform films. In particular, depositing halide precursors such as Pbl₂ and PbBr₂ together is known to form poorly mixed phases, which, because they are not homogeneously intermixed, create a diffusion barrier to organic cations and therefore inhibit perovskite formation. These compounds don't intermix very well due to their different thin film crystalline or polycrystalline structures, which then prevent formation of a solid solution and accordingly, formation of a pure and stable perovskite. Mixed halide perovskites are particularly important for photovoltaic applications, as varying the ratio of halides tunes the bandgap of the material, allowing for optimization of the light-harvesting properties of the perovskite photoactive region. The tunability of these mixed halide compositions also makes them suitable materials for a number of different cell configurations, such as single-junction cells and multi-junction cells where their bandgaps can be adapted to match a variety of absorbing materials in the adjoining cells.

The process of the present invention provides a clear solution to the problems experienced in the art; the use of a sequential deposition method to produce superior quality mixed-halide perovskite films, in particular where the metal halide deposition steps are kept separate. Said method yields a highly crystalline perovskite material and inevitably enhances the overall device characteristics. The method employs a simplified and versatile deposition process which allows for inter-step adjustability of the conditions and step chronology. Further, the claimed sequential process also enables the synthesis of phase pure perovskites with minimal precursor material required at each stage due to the fewer impurities introduced by using the inventive method. As such, the wastage and material costs are also reduced. Overall, the low-control needed, cost-effectiveness, and adaptability of the process facilitates a much easier transition for in-line production on a large scale.

### BRIEF DESCRIPTION OF THE FIGURES

FIGS. 1A and 1B illustrate the XRD patterns for a perovskite FA₁₋ₐCsₐPb(l_{1-y}Br_{y})₃ layer produced via multi-deposition and sequential deposition methods, respectively.

FIG. 2 illustrates an overlay of the XRD patterns for the perovskite layers of FIG. 1 produced via both methods, wherein the continuous line is the sequential method and the dashed line is the multi-deposition method. The stars indicate peaks formed by the impurity CsPb₂X₅ phase in the multi-deposition method.

FIG. 3 shows the current-density (IV) curves of tandem photovoltaic devices produced using the perovskite layers according to FIG. 1, formed via the multi-layer method (circle coordinates) and sequential deposition method (cross coordinates).

FIG. 4A shows the XRD pattern for perovskite films according to the formula in FIG. 1, produced by a fully sequential method (continuous line), and partial sequential method, wherein two precursors are co-deposited (dashed line).

FIG. 4B shows the IV curve for perovskite films according to the formula in FIG. 1, produced by a fully sequential method (continuous line) and partial sequential method, wherein two components are co-deposited (crossed coordinates).

FIG. 5 shows a schematic of a multi-deposition method, wherein the two metal halides are co-deposited together, along with an inorganic halide, to produce a perovskite film. Example materials for each source are provided to produce a perovskite film of the formula in FIG. 1.

FIG. 6 shows a schematic of the sequential deposition method according to the invention, wherein the metal halides are deposited separately, but a metal halide and inorganic halide are co-deposited, to produce a perovskite film. Example materials for each source are provided to produce a perovskite film of the formula in FIG. 1.

FIG. 7 shows a schematic of a fully sequential deposition method, wherein all precursors are deposited in separate steps, to produce a perovskite film. Example materials for each source are provided to produce a perovskite film of the formula in FIG. 1.

FIG. 8 shows a diagrammatic representation of a linear sequential deposition set-up, showing the inter-source distances and evaporation plume overlap and direction, for a set of different component materials onto a substrate.

FIG. 9 shows a diagrammatic representation of a linear sequential deposition set-up wherein the plumes of the sources are not overlapping (A) and wherein the plumes of sources are overlapping (B).

FIG. 10A shows the XRD pattern for perovskite films according to the formula in Example 4, produced by a partial sequential method, wherein two precursors Pbl₂/Csl are co-deposited, followed by sequential depositions of PbBr₂, FAI and GAI.

FIG. 10B shows the IV curve of a tandem solar cell containing perovskite films according to the formula in Example 4, produced by a partial sequential method.

FIG. 11A shows the XRD pattern of perovskite films according to the formula in Example 5, produced by a partial sequential method, wherein two precursors Pbl₂/Csl are co-deposited, followed by sequential depositions of PbBr₂, PbCl₂ and FAI.

FIG. 11B shows the IV curve of a tandem solar cell containing perovskite films according to the formula in Example 5, produced by a partial sequential method.

FIG. 12A shows the XRD pattern of perovskite films according to the formula in Example 6, produced by a partial sequential method.

FIG. 12B shows the IV curve of a tandem solar cell containing perovskite films according to the formula in Example 6, produced by a partly sequential method, wherein two components are co-deposited.

FIG. 13 shows the XRD pattern of perovskite films according to the formula in Example 7, produced by a fully sequential method, comprising the deposition of Snl₂, PbCl₂ and FAI.

FIG. 14 shows the XRD pattern of perovskite films according to the formula in Example 8, produced by a multi-deposition method (not according to the invention).

### DETAILED DESCRIPTION OF INVENTION

The invention provides a method for producing a perovskite material which comprises:
i. The deposition of a first metal halide precursor; and
ii. The deposition of a second metal halide precursor, wherein the halide component in the second metal halide precursor is different from that of the first metal halide precursor and the first and second metal halide precursors are deposited separately; and
iii. The deposition of an inorganic halide precursor; and/or
iv. The deposition of a first organic halide precursor; and
v. Optionally, the deposition of a second organic halide precursor which is different from the first organic halide precursor; and
vi. Optionally, the deposition of a third organic halide precursor which is different from the first and second organic halide precursors;

to form the perovskite material which comprises a mixed halide; wherein steps i., ii. and iii. (if present) are carried out by physical vapour deposition.

In the method of the invention, at least one of steps iii. and iv. must be present, and steps v. and vi. are optional.

In a preferred embodiment of the invention, all steps are carried out by physical vapour deposition, i.e. the invention provides a method for producing a perovskite material wherein precursors are deposited on a substrate by physical vapour deposition; wherein the method comprises:
i. The deposition of a first metal halide precursor; and
ii. The deposition of a second metal halide precursor, wherein the halide component in the second metal halide precursor is different from that of the first metal halide precursor and the first and second metal halide precursors are deposited separately; and
iii. The deposition of an inorganic halide precursor; and/or
iv. The deposition of a first organic halide precursor; and
v. Optionally, the deposition of a second organic halide precursor which is different from the first organic halide precursor; and
vi. Optionally, the deposition of a third organic halide precursor which is different from the first and second organic halide precursors,

to form the perovskite material which comprises a mixed halide. The invention provides a method which produces high-purity and uniform films via a manageable stepwise process. There may be at least three or four (or more) steps. The term “precursor” refers to a material which is a precursor to the final perovskite material, i.e. the precursors are deposited and then react to form the final product. The physical vapour deposition process generally involves thermal evaporation of the precursors into the vapor phase, which vapor phase then generally condenses onto a substrate to form a thin film. The process generally does not involve a chemical reaction step with the substrate.

Any steps which do not take place by physical vapour deposition (for instance, the deposition of any of the organic halide precursors) may take place by any means which effectively deposit the material. The organic halide precursors, for instance, may be deposited by solution deposition. However, in a preferred embodiment all steps take place by physical vapor deposition.

The steps may be carried out in any order.

The mixed halide material is a perovskite which comprises two or more different halide anions. There are preferably two different halide anions, but in a different embodiment, three different halide anions may be present.

The method may further comprise a final annealing step, (vii), whereby the deposited material is heated to improve the morphology and crystallinity of the final film. The final annealing step may be carried out under vacuum or in air at atmospheric pressure. Temperatures are bespoke to the evaporation temperatures of each precursor material and may, for instance, range from 80° C. to 800° C., with a consistent pressure of approximately 10-6 to 10-5 mbar, depending on the tool set-up used. For example, the deposition temperature of PbBr₂ and Pbl₂ are estimated at >380° C. In some cases, the structural properties of the film can be further improved by further performing intermittent annealing steps between depositions.

The process of the invention may be carried out under vacuum, generally by vacuum deposition onto a substrate. This may be carried out in a vacuum chamber at base pressure of approximately 10⁻⁷ to 10⁻³ mbar, for example under N₂ atmosphere. The chamber may be equipped with individual evaporation sources, each containing a precursor.

It is important that the first and second metal halide precursors are deposited separately in separate, distinct steps.

The steps in the method may be carried out sequentially—that is, one after the other with no or minimal overlap.

Each step may be carried out consecutively, such that the method is a fully sequential deposition process. Alternatively, the method may be a partial sequential deposition process, wherein at least steps (i) and (ii) are deposited sequentially. The term “sequential deposition”, when steps take place by physical vapour deposition, refers to a stepwise consecutive vapour deposition process of individual precursors from their respective evaporation sources, whereby there may be a minimal degree of overlap of precursor deposition between each step. This minimal overlap refers to an allowance of up to 10% (and preferably up to 5%) of the precursor plume from the previous step to mix with that of the precursor plume of the subsequent deposition step (i.e. the adjacent source) as the precursors are evaporated. The amount of plume overlap can be measured by modelling the sequential deposition tool set-up and inputting the relevant materials and conditions (e.g. inter source distances, temperatures, evaporation rates, source angle etc.) information. Alternatively, thin film compositional mixtures generated by overlapping plumes can be measured post deposition using depth profiling scientific methods, such as Time-of-Flight Secondary Ion Mass Spectrometry (ToF-SIMS).

Repeated depositions of each precursor can be performed to obtain a multi-layer stack. The term multi-layer stack refers to a stack of two or more different thin films. For example, a stack may have the configuration (AB), where A and B are two distinct films and n is the repetition number of the AB bilayer. The same principle is applied to a multi-layer stack with more than two different films.

As mentioned above, there may be some overlap between the various steps in the process. Some of the steps may even take place simultaneously, i.e. at the same time, provided that steps (i) and (ii) are kept separate.

Annealing may optionally be deployed in between steps. The precursors from each step are in solid form and may each be placed in individual crucibles, wherein the crucibles are lined up for sequential deposition. The distance of separation between the crucibles (sources) determines whether the precursors are deposited in a substantially sequential fashion or at the same time (as illustrated by FIG. 8). For example, two crucibles may be close enough to essentially deposit together, while the third crucible is far enough to deposit sequentially.

Further, any of steps (i) to (vi) can be repeated one or more times to achieve a particular film thickness. In one embodiment, an order of steps may be pre-determined, which upon completion would represent a single cycle. The cycle can then further be repeated one or more times to create a deposition cycle. The number of cycle repetitions can dictate the thickness and final composition of the perovskite material.

The final perovskite material may be a perovskite of typical ABX₃ formula or a double perovskite of A₂BX₆ formula. The final formed perovskite material will be a thin film with a thickness in the range of 50 nm to 2000 nm, preferably 100 nm to 1500 nm, and yet more preferably 300 to 1200 nm.

FIG. 8 shows an example set-up of a linear sequential deposition process, wherein different materials (A, B, C) are contained in each source and the distance between said sources can vary (d₁). Accordingly, the inter-source distances influence the amount of plume overlap (d₂).

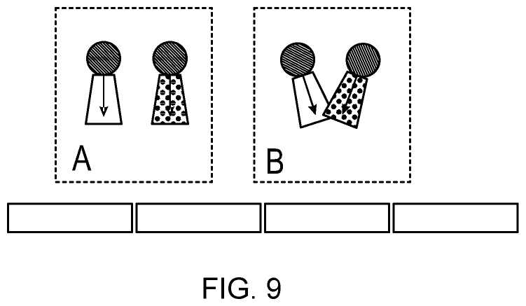

The angle of the adjacent sources may also influence the amount of plume overlap. FIG. 9 shows that when the sources are not angled towards each other and far enough apart, no plume overlap is expected and thus a discrete deposition will result from each source (A). FIG. 9 also shows that when two sources are close enough and angled towards each other (B), there is some plume overlap, such that the materials are deposited onto the substrate at substantially the same time (co-deposited).

Any order of the deposition steps can be deployed, with any of the steps being repeatable, wherein the same material or step may even be consecutively repeated.

### Step (i)

Step (i) of the method of the invention involves the deposition of a precursor which is a first metal halide from an evaporation source onto a substrate. The metal halide may be initially present in solid form and sublimed at the required temperature of the individual precursor, such that the precursor travels in the gas phase and eventually deposits as a solid film upon contact with the substrate. Step (i) is not restricted to being performed first in the method, but can be performed at any point.

In a preferred embodiment the metal halide may be a salt of formula BX₂, wherein B comprises a divalent metal cation preferably selected from Pb²⁺ or Sn²⁺; and X is a halide anion, selected from Cl⁻, Br, I⁻, preferably wherein X is Br or I. The BX₂ metal halide salt may be in any solid form, including powder, pelletised, or granular etc., and may be evaporated at a temperature according to the sublimation temperature of the salt identity. Preferably, the deposited film is selected from Pbl₂, PbBr₂, PbCl₂, SnF₂, SnCl₂, Snl₂ and SnBr₂. Preferably the final perovskite film is that of a typical perovskite formula ABX₃, wherein A, B and X may comprise one or more different A, B and X ions occupying each respective site.

In another embodiment, the metal halide be a salt of formula BX, wherein B comprises a monovalent metal cation preferably selected from Ag⁺, Au⁺, In⁺, more preferably wherein B is selected from Ag⁺; and X is a halide anion selected from Cl⁻, Br, I⁻, preferably wherein X is Br or I. The BX metal halide salt may be in any solid form, including powder, pelletised, or granular etc., and may be evaporated at a temperature range selected according to the sublimation temperature of the salt identity. Preferably, the deposited film is selected from Agl and AgBr.

The metal halide is not to be confused with the inorganic halide which is used in later steps of the method of the invention. Accordingly, the metal halide does not have formula AX as defined for the inorganic halide below. The cation in the metal halide is not derived from an alkali metal. For instance, the metal halide does not have formula AX, wherein A comprises a monovalent inorganic cation for instance selected from Cs⁺, K⁺, Rb⁺, and X is a halide anion.

In another embodiment, the metal halide be a salt of formula BX₃, wherein B comprises a trivalent metal cation preferably selected from Bi³⁺, Al³⁺, Sb³⁺, Ge³⁺ and Ga³⁺, more preferably wherein B is selected from Bi³⁺ and Al³⁺; and X is a halide anion selected from Cl⁻, Br⁻, I⁻, preferably wherein X is Br⁻ or I⁻. The BX₂ metal halide salt may be in any solid form, including powder, pelletised, or granular etc., and may be evaporated at a temperature range according to the sublimation temperature of the salt identity. Preferably, the deposited film is selected from Bil₃, BiBr₃, All₃ and AlBr₃.

In another embodiment, an additional metal halide precursor with a different halide component to those of steps (i) and (ii) may be included in the process as an additive. This additional halide component is not present in the final perovskite formula. Preferably, the additional metal halide precursor acting as an additive is PbCl₂. These additives can suitably be incorporated into any other embodiment described herein.

### Step (ii)

Step (ii) of the method of the invention involves the deposition of a precursor which is a second metal halide from an evaporation source onto a substrate. Step (ii) is separate to step (i), i.e. the plumes of the first and second metal halide precursors do not intermix by more than 10% (and preferably by no more than 5%), such that the two precursors are not deposited in a single step. Generally, the precursor of step (ii) is provided in a separate source to the precursor of step (i). The metal halide may be initially present in solid form and sublimed at the required temperature of the individual precursor. Step (ii) is not restricted to being performed in a particular order, but can be performed at any point, provided it is separate from step (i)

In a preferred embodiment the metal halide of step (ii) may be a salt of formula BX₂ as defined in step (i), but wherein the halide component is different to that of step (i). Preferably, the deposited precursor is selected from PbCl₂, Pbl₂, PbBr₂, SnCl₂, SnF₂, Snl₂ and SnBr₂.

In a preferred embodiment, the deposition in steps (i) and (ii) may include the following preferred precursors:
Pbl₂ and PbBr₂
Pbl₂ and SnBr₂
Snl₂ and SnBr₂
PbBr₂ and Snl₂;
Snl₂ and PbCl₂

wherein each precursor may be deposited in either of steps (i) and (ii).

In another embodiment, the metal halide of step (ii) may be a salt of formula BX as defined in step (i), however, when BX is the precursor in step (ii), BX₃ is preferably the precursor in step (i). Similarly, in the embodiment wherein the metal halide of step (ii) may be a salt of formula BX₃ as defined in step (i), then BX is preferably the precursor in step (i). The halide components in steps (i) and (ii) are different.

In the embodiments where the metal halide in steps (i) and (ii) may be selected from BX and BX₃, the final perovskite film is that of a double perovskite formula A₂BX₆, otherwise written as A₂(B′B″)X₆.

In another embodiment, a final triple mixed halide may be formed by repeating one of steps (i) or (ii) with a metal halide which has a different halide component to those already deposited previously in steps (i) and (ii). For example, PbBr₂ may be deposited in step (i), Pbl₂ may be deposited in step (ii) and step (i) or (ii) may be repeated but with the deposition of PbCl₂ instead. The steps may be performed in any order and repeated as many times as desired, provided no steps which involve metal halide precursors are co-evaporated with each other. Where metal halide precursors have the same structure, they may be co-evaporated. For example, PbCl₂ and PbBr₂ which both have an orthorhombic lattice may be co-deposited and still form a crystalline well-mixed film.

Step (iii)

Step (iii) of the method of the invention involves the deposition of an inorganic halide from an evaporation source onto a substrate. The inorganic halide is generally initially present in solid form and sublimed at the required temperature of the individual precursor. Step (iii) is not restricted to being performed in a particular order but can be carried out any point.

The inorganic halide may be of formula AX, wherein A comprises a monovalent inorganic cation, typically an alkali metal cation, and preferably selected from Cs⁺, K⁺, Rb⁺, more preferably wherein A is Cs⁺; and X is a halide anion selected from Cl⁻, Br, I⁻, preferably wherein X is Br or l′. In a preferred embodiment AX is selected from Csl and CsBr.

As detailed above, the inorganic halide is not the same as the metal halide used in step (i).

In one embodiment the precursor from step (iii) may be co-evaporated with one of the precursors from either step (i) or (ii), to essentially deposit onto the substrate in a single step. For example, Pbl₂ from step (i) or (ii) and Csl from step (iii) may be co-evaporated.

The term co-evaporation means that evaporation from each source occurs somewhat at the same time, such that the evaporation periods for each source overlap with each other. As mentioned above, the overlap refers to the percentage mixing of the plumes of each precursor and is generally determined by the distance between the evaporation sources and/or their respective angles. Two sources which are in close enough proximity and angled towards each other may deposit with enough overlap to constitute “co-evaporation” and thus represent a single deposition step. Furthermore, a simultaneous co-evaporation step may also optionally be carried out, which involves depositing the precursors from two close sources at the substantially the same time.

Thus, there is provided a method for producing a perovskite material wherein there are two or more sequential deposition steps comprising:
i. The deposition of a first metal halide; and
ii. The co-evaporation deposition of a second metal halide with an inorganic halide;
and/or
iii. The deposition of a first organic halide; and
iv. Optionally, the deposition of a second organic halide which is different from the first, and
v. Optionally, the deposition of a third organic halide which is different from the first and second, to form the perovskite material which comprises a mixed halide. The steps may be carried out in any order.

### Step (iv)

Step (iv) of the method of the invention involves the deposition of an organic halide onto a substrate. Preferably, the organic halide is deposited from an evaporation source but may be deposited by other means, such as solution deposition. In one embodiment, the organic halide is initially present in solid form and sublimed at the required temperature of the individual precursor. Step (iv) can be performed in any order

The organic halide may be of formula A′X, wherein A′ comprises a monovalent organic cation such as formamidinium (FA⁺), methylammonium (MA⁺) or ethylammonium (EA⁺), preferably wherein A is selected from MA⁺ and FA⁺; and X is a halide anion selected from Cl⁻, Br, I⁻, preferably wherein X is Br or l′. In a preferred embodiment A′X is selected from MAI, MABr, FAI and FABr.

In a preferred embodiment, the precursors in each step are; (i) is BX₂; (ii) is a different BX₂ to (i); (iii) is AX and (iv) is A′X, to form a typical ABX₃ perovskite structure, wherein A, B and X may comprise one or more different A, B and X ions occupying each respective site.

In an alternative embodiment, the precursors in steps (i) and (ii) are selected from BX and BX₃; (iii) is AX and (iv) is A′X, to form a double A₂BX₆ perovskite structure.

### Steps (v) and (vi)

Step (v) and (vi) of the method of the invention are both optional steps, which involve the deposition of a second and a third organic halide, respectively, onto a substrate. The second and third organic halides, if present, are generally deposited from separate evaporation sources onto a substrate. In one embodiment, the organic halides are initially present in solid form and sublimed at the required temperature of the individual precursor. Steps (v) and (vi) can be performed in any order.

The organic halide of step (v) may be of formula A″X, wherein A″X is different to A′X from step (iv). Preferably, A″ comprises a monovalent organic cation such as FA⁺, MA⁺, EA⁺ guanidinium (GA⁺), benzylammonium (BzA⁺), dimethylammonium ((DMA⁺), Imidazolium (Im⁺), Acetamidinium (Ac⁺), Phenylethylammonium (PEA⁺) and butylammonium (BA⁺), further preferably wherein A″ is selected from MA⁺, FA⁺, EA⁺ and GA⁺; and X is a halide anion selected from Cl⁻, Br, I⁻, preferably wherein X is Br or I. In a preferred embodiment A″X is selected from MAI, MABr, FAI, FABr, GAI and GABr.

The organic halide of step (vi) may be of formula A″ “′X, wherein A″X is different to A′X from step (iv) and A″X from step (V). Preferably, A”′ comprises a monovalent organic cation such as FA⁺ MA⁺, EA⁺. GA⁺, DMA⁺, Im⁺, Act, PEA⁺, BzA⁺ and BA⁺, further preferably wherein A″ is selected from FA, MA and GA⁺; and X is a halide anion selected from Cl⁻, Br, I⁻, preferably wherein X is Br or I. In a preferred embodiment A″X is selected from MAI, MABr, FAI, FABr, GAI, GABr.

In a preferred embodiment, only one of step (v) or (vi) are present and the final perovskite formula is AA′A″BX₃. In a further preferred embodiment, steps (v) and (vi) are both present, and the final perovskite is of formula AA′A″A′″BX₃. The final perovskite formula may further comprise multiple B and X ions.

In an alternative embodiment, only one of step (v) or (vi) are present and the final perovskite formula is (AA′A″)₂BX₆. In yet another embodiment, steps (v) and (vi) are both present and the final perovskite is of formula (AA′A″A″)₂BX₆. The final perovskite formula may further comprise multiple B and X ions.

In one embodiment, any two of the organic precursors from steps (iv) to (vi) may be co-evaporated with one another, to essentially deposit onto the substrate in a single step. For example, FAI from step (iv) may be co-evaporated with the precursor MAI from step (v); or the precursor GAI from step (vi).

Thus, there is provided a method for producing a perovskite material wherein there are three or more sequential deposition steps comprising:
i. The deposition of a first metal halide; and
ii. The deposition of a second metal halide; and
iii. The deposition of an inorganic halide; and/or
iv. The co-evaporation deposition of a first organic halide with a second organic halide; and
v. Optionally, the deposition of a third organic halide which is different from the first and second,

to form the perovskite material which comprises a mixed halide. The steps may be carried out in any order.

In another embodiment there may be two or more steps where simultaneous co-evaporation takes place. These two or more steps wherein simultaneous co-evaporation takes place may be derived from one of the precursors of steps (i) or (ii) with the precursor of step (iii) and/or from any two of the precursors from steps (iv) to (vi).

Thus, there is provided a method for producing a perovskite material wherein there are three or more sequential deposition steps comprising:
i. The deposition of a first metal halide; and
ii. The co-evaporation deposition of a second metal halide with an inorganic halide; and
iii. The co-evaporation deposition of a first organic halide with a second organic halide; and
v. Optionally, the deposition of a third organic halide which is different from the first and second,

to form the perovskite material which comprises a mixed halide. The steps may be carried out in any order.

In one embodiment any of the precursors from step (i) to (vi) may be co-evaporated with one another, except the precursors from steps (i) and (ii), which must always be sequentially deposited with respect to each other. During co-evaporation, the precursors in their separate sources essentially deposit onto the substrate in a single step. For example, Pbl₂ from step (i) or (ii) and Csl from step (iii) may be co-evaporated. The depositions may occur in any order.

In another embodiment there may be two or more steps where co-evaporation occurs. These two or more steps wherein co-evaporation takes place may be derived from any combination of the precursors from step (i) to (vi), except the precursors from step (i) and (ii). The depositions may occur in any order.

In some embodiments, organic halides may be included in the process as an additive. These additives are not present in the final perovskite formula, but instead act as defect passivating additives at grain boundaries and surfaces. Typically, these additives comprise a monovalent organic A cation which has an ionic radius which is larger than 2.53 Å, herein referred to as “large” A cations. Preferably, the monovalent organic cation is selected from EA⁺, GA⁺, BzA⁺, DMA⁺, Im⁺, Ac⁺, PEA⁺ and BA⁺. These additives can suitably be incorporated into any other embodiment described herein. The respective radii for such organic cations in perovskite environments can be found for instance in Cheetham et al., Chem. Sci., 2015, 6, 3430 and Travis et al., Chem. Sci., 2016, 7, 4548-4556.

### Material

Typically, the method of the invention comprises the formation of a thin film mixed-halide perovskite material, wherein the bandgap is typically between 1.1 eV and 2.5 ev.

The perovskite material is a mixed halide material—i.e. it comprises two or more different halide anions. Generally, the halide anions are selected from I, Cl and Br.

In a preferred embodiment of the invention, the perovskite material comprises two or more monovalent cations.

In one embodiment of the invention, a perovskite of formula ABX₃ is produced, wherein the cation in the A position does not comprise (or does not consist of) methylammonium (MA). In a preferred embodiment, the A site cations comprise a monovalent organic cation and/or a monovalent inorganic cation. The monovalent inorganic cation is preferably Cs. The organic cation is preferably FA. The B site preferably comprises Pb. Preferably there are two or more different halide anions present. In one embodiment, there may be three different halide anions present.

Preferably, the perovskite material formed by the method of the invention has the formula (I):

AₐA′_{b}A″_{c}A″_{d}BₓB′₁₋ₓ(X_{y}X′_{1-y})₃,

wherein;
A is a monovalent inorganic cation;
A′ is a first monovalent organic cation;
A″ is a second monovalent organic cation;
A′″ is a third monovalent organic cation;
wherein all A cations A, A′, A″ and A″ are different from each other and;
B is a divalent metal cation;
B′ is a different divalent metal cation to B;
X is a halide anion;

and X′ is a different halide anion to X;

$$0 \leq a < 1 \\ 0 \leq b < 1 \\ 0 \leq c < 1 \\ 0 \leq d < 1 \\ a + b + c + d = 1 \\ 0 \leq x < 1 ; and 0 < y < 1 ;$$

B and B′ are independently divalent metal cations;
and X and X′ are halide anions.

In a preferred embodiment 0<a<1 and/or 0<b<1.

In one embodiment the method may comprise steps (i)-(v), whereby each step is carried out sequentially, to yield a final triple cation mixed halide perovskite. Preferably the material is a triple cation double halide perovskite.

In another embodiment the method may comprise steps (i)-(vi), whereby each step is carried out sequentially, to yield a final quadruple cation mixed halide perovskite. Preferably the material is a quadruple cation double halide perovskite.

One particularly preferred material is FA₁₋ₐCSₐPb(I_{1-y}Br_{y})₃ wherein x and y are independently in the range 0.05-0.95. In a preferred embodiment, y is in the range 0.1-0.4 and x is in the range 0.1-0.5.

In another embodiment, the perovskite material formed by the method of the invention is a double perovskite of formula (II):

(AₐA′_{b})₂(BₓB′₁₋ₓ)(X_{y}X′_{1-y})₆,
wherein;
A is a monovalent inorganic cation;
A′ is a first monovalent organic cation;
B is a trivalent metal cation;
B′ is a monovalent metal cation;
X is a halide anion;
and X′ is a different halide anion to X,
0≤a≤1

$$0 \leq b < 1 \\ a + b = 1 \\ 0 < x < 1 \\ and 0 < y < 1 ,$$

wherein the material is a double or 2D perovskite.

In a further embodiment of the invention is provided a semiconductor device having a photoactive layer comprising an organic-inorganic mixed halide perovskite material formed according to the first aspect of the invention.

In another embodiment, the semiconductor device is a photovoltaic device with a photoactive region, wherein the photoactive region comprises a thin film of the perovskite material formed according to the first aspect of the invention, with the thickness of the thin film of the perovskite material being in the range from 50 nm to 2000 nm. Further, the photoactive region may comprise: an n-type region comprising at least one n-type layer; and a layer of the perovskite material in contact with the n-type region.

The photovoltaic device may comprise an n-type region comprising at least one n-type layer; a p-type region comprising at least one p-type layer; and a layer of the perovskite material disposed between the n-type region and the p-type region. The photovoltaic device configuration can therefore have a regular n-i-p structure or inverted p-i-n structure.

In another embodiment of the present invention is provided a multijunction photovoltaic device, wherein the device comprises two or more sub-cells, the first sub cell comprising a photovoltaic device as defined above, and a further sub-cell comprising a photoactive layer having a bandgap of between 1.1 and 2.5 ev. The bandgaps of the respective sub-cells are both tuneable within this range.

In one embodiment of the invention, the photovoltaic device may be a single junction device. In another embodiment, the photovoltaic device may be multi-junction device, wherein according to the geometry, the top, middle or bottom sub-cell comprises a perovskite as described herein, in an all-perovskite, perovskite-Si, perovskite-ClGS, perovskite-CdTe, perovskite-CuZnSnSSe, or perovskite-CuZnSnS, heterojunction device.

In another embodiment of the present invention is provided an optoelectronic device comprising the perovskite material formed according to the first aspect of the invention.

In some embodiments, the substrate may be a flat planar surface. Alternatively, the substrate may be a textured surface with root mean square roughness (Rims) of greater than or equal to 50 nm. The material of the substrate may be selected from glass, fluorine-doped tin oxide (FTO), Indium tin oxide (ITO), or Si substrate.

### Definitions

The term “inorganic halide” refers to a compound which comprises an inorganic metal cation bonded to one or more halide anion components, subject to the balancing of the respective valences of cation(s) and anion(s). Preferably the inorganic metal cations are selected from alkali or alkaline-earth metals.

The term “metal halide” refers to a compound which comprises a metal cation bonded to one or more halide anion components, subject to the balancing of the respective valences of cation(s) and anion(s). Preferably the metal cation is a monovalent, divalent, or trivalent metal which is not from Groups 1 or 2 from the periodic table.

The term “organic halide” refers to a compound which comprises an organic cation bonded to one or more halide anion components subject to the balancing of the respective valences of the cation(s) and anion(s). Preferably an organic halide comprises a monovalent ammonium cation singly bonded to a halide anion to form an ammonium halide.

The term “deposition cycle” refers to a particular ordered linear sequence comprised of a discrete number of vapour depositions which once completed constitute a single “cycle”. Once one “cycle” has been completed, the process be repeated or “cycled” one or more times to achieve a perovskite with a desired thickness. The term “linear” sequence refers to a process whereby a single deposition step is mostly dealt with at one point and once completed, proceeds to the next deposition step.

The term “double perovskite” refers to a perovskite composition which can host two different transition metal cations in the B sites, one which is a monocation and the other a trication, such that the overall general formula is A₂(B^{l}B^{ll})X₆, wherein A consist of one or more organic and/or inorganic monocations, B^{l} consists of one or more metal monocations, B^{lll} consists of one or more metal trications and X is a halide.

The term “photoactive”, as used herein, refers to a region, layer or material that is capable of responding to light photoelectrically. A photoactive region, layer or material is therefore capable of absorbing the energy carried by photons in light that then results in the generation of electricity (e.g. by generating either electron-hole pairs or excitons).

The term “perovskite”, as used herein, refers to a material with a three-dimensional crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0,0,0), the B cations are at (1/2, 1/2, 1/2) and the X anions are at (1/2, 1/2, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄ type structure comprises a layer of perovskite material. The skilled person will appreciate that a perovskite material can be represented by the formula [A][B][X]₃, wherein [A] is at least one cation, [B] is at least one cation and [X] is at least one anion. When the perovskite comprises more than one A cation, the different A cations may distributed over the A sites in an ordered or disordered way. When the perovskite comprises more than one B cation, the different B cations may distributed over the B sites in an ordered or disordered way. When the perovskite comprise more than one X anion, the different X anions may distributed over the X sites in an ordered or disordered way. The symmetry of a perovskite comprising more than one A cation, more than one B cation or more than one X cation, will often be lower than that of CaTiO₃.

As mentioned in the preceding paragraph, the term “perovskite”, as used herein, refers to (a) a material with a three-dimensional crystal structure related to that of CaTiO₃ or (b) a material comprising a layer of material, wherein the layer has a structure related to that of CaTiO₃. Although both of these categories of perovskite may be used in the devices according to the invention, it is preferable in some circumstances to use a perovskite of the first category, (a), i.e. a perovskite having a three-dimensional (3D) crystal structure. Such perovskites typically comprise a 3D network of perovskite unit cells without any separation between layers. Perovskites of the second category, (b), on the other hand, include perovskites having a two-dimensional (2D) layered structure. Perovskites having a 2D layered structure may comprise layers of perovskite unit cells that are separated by (intercalated) molecules; an example of such a 2D layered perovskite is [2-(1-cyclohexenyl)ethylammonium]2PbBr₄. 2D layered perovskites tend to have high exciton binding energies, which favours the generation of bound electron-hole pairs (excitons), rather than free charge carriers, under photoexcitation. The bound electron-hole pairs may not be sufficiently mobile to reach the p-type or n-type contact where they can then transfer (ionise) and generate free charge. Consequently, in order to generate free charge, the exciton binding energy has to be overcome, which represents an energetic cost to the charge generation process and results in a lower voltage in a photovoltaic cell and a lower efficiency. In contrast, perovskites having a 3D crystal structure tend to have much lower exciton binding energies (on the order of thermal energy) and can therefore generate free carriers directly following photoexcitation. Accordingly, the perovskite semiconductor employed in the devices and processes of the invention is preferably a perovskite of the first category, (a), i.e. a perovskite which has a three-dimensional crystal structure. This is particularly preferable when the optoelectronic device is a photovoltaic device.

The perovskite material employed in the present invention is one which is capable of absorbing light and thereby generating free charge carriers. Thus, the perovskite employed is a light-absorbing perovskite material. However, the skilled person will appreciate that the perovskite material could also be a perovskite material that is capable of emitting light, by accepting charge, both electrons and holes, which subsequently recombine and emit light. Thus, the perovskite employed may be a light-emitting perovskite.

As the skilled person will appreciate, the perovskite material employed in the present invention may be a perovskite which acts as an n-type, electron-transporting semiconductor when photo-doped. Alternatively, it may be a perovskite which acts as a p-type hole-transporting semiconductor when photo-doped. Thus, the perovskite may be n-type or p-type, or it may be an intrinsic semiconductor. In preferred embodiments, the perovskite employed is one which acts as an n-type, electron-transporting semiconductor when photo-doped. The perovskite material may exhibit ambipolar charge transport, and therefore act as both n-type and p-type semiconductor. In particular, the perovskite may act as both n-type and p-type semiconductor depending upon the type of junction formed between the perovskite and an adjacent material.

Typically, the perovskite semiconductor used in the present invention is a photosensitizing material, i.e. a material which is capable of performing both photogeneration and charge transportation.

The term “mixed-halide”, as used herein, refers to a compound comprising at least two different halides. The term “halide” refers to an anion of an element selected from Group 17 of the Periodic Table of the Elements, i.e., of a halogen. Typically, halide anion refers to a fluoride anion, a chloride anion, a bromide anion, an iodide anion or an astatide anion.

The term “metal halide perovskite”, as used herein, refers to a perovskite, the formula of which contains at least one metal cation and at least one halide anion. The term “organometal halide perovskite”, as used herein, refers to a metal halide perovskite, the formula of which contains at least one organic cation.

The term “organic material” takes its normal meaning in the art. Typically, an organic material refers to a material comprising one or more compounds that comprise a carbon atom. As the skilled person would understand it, an organic compound may comprise a carbon atom covalently bonded to another carbon atom, or to a hydrogen atom, or to a halogen atom, or to a chalcogen atom (for instance an oxygen atom, a sulphur atom, a selenium atom, or a tellurium atom). The skilled person will understand that the term “organic compound” does not typically include compounds that are predominantly ionic such as carbides, for instance.

The term “organic cation” refers to a cation comprising carbon. The cation may comprise further elements, for example, the cation may comprise hydrogen, nitrogen or oxygen. The term “inorganic cation” refers to a cation that is not an organic cation. By default, the term “inorganic cation” refers to a cation that does not contain carbon.

The term “semiconductor”, as used herein, refers to a material with electrical conductivity intermediate in magnitude between that of a conductor and a dielectric. A semiconductor may be an n-type semiconductor, a p-type semiconductor or an intrinsic semiconductor.

The term “n-type”, as used herein, refers to a region, layer or material that comprises an extrinsic semiconductor with a larger concentration of electrons than holes. In n-type semiconductors, electrons are therefore majority carriers and holes are the minority carriers, and they are therefore electron transporting materials. The term “n-type region”, as used herein, therefore refers to a region of one or more electron transporting (i.e. n-type) materials.

Similarly, the term “n-type layer” refers to a layer of an electron-transporting (i.e. an n-type) material. An electron-transporting (i.e. an n-type) material could be a single electron-transporting compound or elemental material, or a mixture of two or more electron-transporting compounds or elemental materials. An electron-transporting compound or elemental material may be undoped or doped with one or more dopant elements.

The term “p-type”, as used herein, refers to a region, layer or material that comprises an extrinsic semiconductor with a larger concentration of holes than electrons. In p-type semiconductors, holes are the majority carriers and electrons are the minority carriers, and they are therefore hole transporting materials. The term “p-type region”, as used herein, therefore refers to a region of one or more hole transporting (i.e. p-type) materials. Similarly, the term “p-type layer” refers to a layer of a hole-transporting (i.e. a p-type) material. A hole-transporting (i.e. a p-type) material could be a single hole-transporting compound or elemental material, or a mixture of two or more hole-transporting compounds or elemental materials. A hole-transporting compound or elemental material may be undoped or doped with one or more dopant elements.

The term “bandgap”, as used herein, refers to the energy difference between the top of the valence band and the bottom of the conduction band in a material. The skilled person may readily measure the bandgap of a material without undue experimentation.

The term “layer”, as used herein, refers to any structure which is substantially laminar in form (for instance extending substantially in two perpendicular directions, but limited in its extension in the third perpendicular direction). A layer may have a thickness which varies over the extent of the layer. Typically, a layer has approximately constant thickness. The “thickness” of a layer, as used herein, refers to the average thickness of a layer. The thickness of layers may easily be measured, for instance by using microscopy, such as electron microscopy of a cross section of a film, or by surface profilometry for instance using a stylus profilometer.

In addition, polycrystalline materials are solids that are composed of a number of separate crystallites or grains, with grain boundaries at the interface between any two crystallites or grains in the material. A polycrystalline material can therefore have both interparticle/interstitial porosity and intraparticle/internal porosity. The terms “interparticle porosity” and “interstitial porosity”, as used herein, refer to pores between the crystallites or grains of the polycrystalline material (i.e. the grain boundaries), whilst the terms “intraparticle porosity” and “internal porosity”, as used herein, refer to pores within the individual crystallites or grains of the polycrystalline material. In contrast, a single crystal or monocrystalline material is a solid in which the crystal lattice is continuous and unbroken throughout the volume of the material, such that there are no grain boundaries and no interparticle/interstitial porosity.

The term “compact layer”, as used herein, refers to a layer without mesoporosity or macroporosity. A compact layer may sometimes have microporosity or nanoporosity.

The term “scaffold material”, as used herein, therefore refers to a material that is capable of acting as a support for a further material. The term “porous scaffold material”, as used herein, therefore refers to a material which is itself porous, and which is capable of acting as a support for a further material.

The term “transparent”, as used herein, refers to material or object allows visible light to pass through almost undisturbed so that objects behind can be distinctly seen. The term “semi-transparent”, as used herein, therefore refers to material or object which has a transmission (alternatively and equivalently referred to as a transmittance) to visible light intermediate between a transparent material or object and an opaque material or object. Typically, a transparent material will have an average transmission for visible light (generally light with a wavelength of from 370 to 740 nm) of around 100%, or from 90 to 100%. Typically, an opaque material will have an average transmission for visible light of around 0%, or from 0 to 5%. A semi-transparent material or object will typically have an average transmission for visible light of from 10 to 90%, typically 40 to 60%. Unlike many translucent objects, semi-transparent objects do not typically distort or blur images. Transmission for light may be measured using routine methods, for instance by comparing the intensity of the incident light with the intensity of the transmitted light.

The term “electrode”, as used herein, refers to a conductive material or object through which electric current enters or leaves an object, substance, or region. The term “negative electrode”, as used herein, refers to an electrode through which electrons leave a material or object (i.e. an electron collecting electrode). A negative electrode is typically referred to as an “anode”. The term “positive electrode”, as used herein, refers to an electrode through which holes leave a material or object (i.e. a hole collecting electrode). A positive electrode is typically referred to as a “cathode”. Within a photovoltaic device, electrons flow from the positive electrode/cathode to the negative electrode/anode, whilst holes flow from the negative electrode/anode to the positive electrode/cathode.

The term “front electrode”, as used herein, refers to the electrode provided on that side or surface of a photovoltaic device that it is intended will be exposed to sun light. The front electrode is therefore typically required to be transparent or semi-transparent so as to allow light to pass through the electrode to the photoactive layers provided beneath the front electrode. The term “back electrode”, as used herein, therefore refers to the electrode provided on that side or surface of a photovoltaic device that is opposite to the side or surface that it is intended will be exposed to sun light.

The term “charge transporter” refers to a region, layer or material through which a charge carrier (i.e. a particle carrying an electric charge), is free to move. In semiconductors, electrons act as mobile negative charge carriers and holes act as mobile positive charges. The term “electron transporter” therefore refers to a region, layer or material through which electrons can easily flow and that will typically reflect holes (a hole being the absence of an electron that is regarded as a mobile carrier of positive charge in a semiconductor). Conversely, the term “hole transporter” refers to a region, layer or material through which holes can easily flow and that will typically reflect electrons.

The term “volatile compound”, as used herein, refers to a compound which is easily removed by evaporation or decomposition. For instance a compound which is easily removed by evaporation or decomposition at a temperature of less than or equal to 150° C., or for instance at a temperature of less than or equal to 100° C., would be a volatile compound. “Volatile compound” also includes compounds which are easily removed by evaporation via decomposition products. Thus, a volatile compound X may evaporate easily thorough evaporation of molecules of X, or a volatile compound X may evaporate easily by decomposing to form two compounds Y and Z which evaporate easily. For instance, ammonium salts can be volatile compounds, and may either evaporate as molecules of the ammonium salt or as decomposition products, for instance ammonium and a hydrogen compound (e.g. a hydrogen halide). Thus, a volatile compound X may have a relatively high vapour pressure (e.g. greater than or equal to 500 Pa) or may have a relatively high decomposition pressure (e.g. greater than or equal to 500 Pa for one or more of the decomposition products), which may also be referred to as a dissociation pressure.

The term “conform”, as used herein, refers to an object that is substantially the same in form or shape as an another object. A “conformal layer”, as used herein, therefore refers to a layer of material that conforms to the contours of the surface on which the layer is formed. In other words, the morphology of the layer is such that the thickness of the layer is approximately constant across the majority of the interface between the layer and the surface on which the layer is formed.

### Photovoltaic Device

The perovskite material of the present invention may be used in a semiconductor device, preferably a photovoltaic device. The perovskite material is advantageously configured to function as a light absorber/photosensitiser within the photoactive region of a photovoltaic device.

The photoactive region may comprise a thin film of the perovskite material, and preferably the thickness of the thin film of the perovskite material is from 50 nm to 2000 nm, preferably 100 nm to 1500, and yet more preferably from 300 to 1200 nm.

The photoactive region may comprise an n-type region comprising at least one n-type layer, and a layer of the perovskite material in contact with the n-type region.

The photoactive region may comprise an n-type region comprising at least one n-type layer, a p-type region comprising at least one p-type layer; and a layer of the perovskite material disposed between the n-type region and the p-type region.

The photoactive region may comprise a layer of the perovskite material without open porosity. The layer of perovskite material may then form a planar heterojunction with one or both of the n-type region and the p-type region.

Alternatively, although less preferably, the layer of the perovskite material may be in contact with a porous scaffold material that is disposed between the n-type region and the p-type region. The porous scaffold material may comprise or consist essentially of any of a dielectric material and a semiconducting/charge transporting material. The layer of the perovskite material may then be disposed within the pores of/be conformal with a surface of the porous scaffold material. Alternatively, the layer of the perovskite material may fill the pores of the porous scaffold material and form a capping layer on the porous scaffold material, wherein the capping layer consists of a layer of the photoactive material without open porosity.

The photovoltaic device may further comprises a first electrode and a second electrode, with the photoactive region being disposed between the first and second electrodes, wherein the first electrode is in contact with the n-type region of the photoactive region and the second electrode is in contact with the p-type region of the photoactive region. The first and second electrode may then comprise a transparent or light transmissive electrically conductive material and the second electrode may comprise a metal or a second light transmissive electrically conductive material. The first electrode may then be an electron collecting electrode, whilst the second electrode is a hole collecting electrode.

The photovoltaic device may further comprise a first electrode and a second electrode, with the photoactive region being disposed between the first and second electrodes, wherein the first electrode is in contact with the p-type region of the photoactive region and the second electrode is in contact with the n-type region of the photoactive region. The first electrode may then comprise a transparent or light transmissive electrically conductive material, and the second electrode may comprise a metal or a second light transmissive electrically conductive material. The first electrode may then be a hole collecting electrode, whilst the second electrode is an electron collecting electrode.

The photovoltaic device may have a multi-junction structure comprising a first sub-cell disposed over a second sub-cell, the first sub-cell comprising the photoactive region comprising the perovskite material. The photovoltaic device may then have a monolithically integrated structure. In a monolithically integrated multi-junction photovoltaic device the two or more photovoltaic sub-cells are deposited directly onto one another and are therefore electrically connected in series. The photovoltaic device may then further comprise an intermediate region connecting the first sub-cell to the second sub-cell, wherein each intermediate region comprises one or more interconnect layers. In a four-terminal (4T) tandem photovoltaic device, the two sub-cells each have two terminals and are deposited separately from each other and then connected via an external circuit, with an electrical insulator between the two sub-cells.

The photovoltaic device having a multi-junction structure may further comprise a first electrode and a second electrode, with the first sub-cell and the second sub-cell disposed between the first and second electrodes.

The first electrode may then be in contact with the p-type region of the first sub-cell, and wherein the first electrode comprises a transparent or semi-transparent electrically conductive material. The first electrode may then be a hole collecting electrode, whilst the second electrode is an electron collecting electrode. In a tandem monolithic device, the second electrode will then be in contact with the second sub-cell, such that the first and second electrodes form the outer components at either end of the device. An intermediate layer is situated between the first and second sub-cells.

Alternatively, the first electrode may be in contact with the n-type region of the first sub-cell, and wherein the first electrode comprises a transparent or semi-transparent electrically conductive material. The first electrode may then be an electron collecting electrode, whilst the second electrode is a hole collecting electrode. In a tandem monolithic device, the second electrode will then be in contact with the second sub-cell, such that the first and second electrodes form the outer components at either end of the device. An intermediate layer is situated between the first and second sub-cells.

When the photovoltaic device has a multi-junction structure the second sub-cell of the photovoltaic device may comprise any of a second perovskite material, crystalline silicon, amorphous silicon, CdTe, CuZnSnSSe, CuZnSnS, or CulnGaSe (ClGS).

As an alternative, the multijunction solar cell can comprise three sub cells. The present invention covers perovskite layers with a bandgap in the range of 1.1-2.5 eV satisfying each of the sub cell requirements in a multi-junction. For example, the top cell having a perovskite layer according to the present invention having a bandgap in the range 2.0-2.5 eV, the middle sub cell having a perovskite layer according to the present invention having a bandgap 1.5 to 2.0 eV, and the bottom sub cell comprising a sub cell having an energy bandgap in the range 1.1 to 1.4 eV, such as for example, crystalline silicon or a narrow bandgap perovskite layer. The bandgaps for each sub-cell may vary with respect to each other and depending on the geometry of the cell. Generally, a top cell may have a wider bandgap and bottom sub-cell may have a lower bandgap, wherein the middle sub-cell bandgap fits somewhere in between these top and bottom sub-cell values. Any of the top, middle, or bottom sub-cells may have a perovskite layer according to the present invention.

For any sub-cells in a multi-junction device which do not employ the perovskite according to the present invention, a perovskite layer may be prepared as described in WO2013/171517, WO2014/045021, WO2016/198889, WO2016/005758, WO2017/089819, and in the reference books “Photovoltaic Solar Energy: From Fundamentals to Applications” edited by Angèl Reinders and Pierre Verlinden, Wiley-Blackwell (2017) ISBN-13:978-1118927465 and “Organic-Inorganic Halide Perovskite Photovoltaics: From Fundamentals to Device Architectures” edited by Nam-Gyu Park et al., Springer (2016) ISBN-13:978-3319351124.

In a preferred device of the present invention, the photoactive layer is a compact layer without open porosity. The standard definitions of the terms “compact layer” and “without open porosity” can be found in WO 2016/079477.

### EXAMPLES

### Example 1

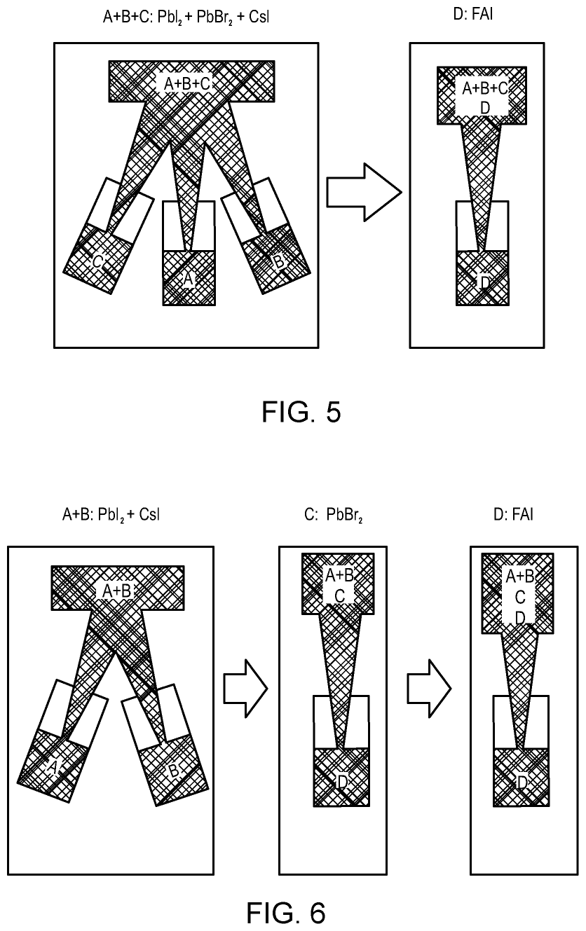

An experiment to compare the results of multi- and sequential deposition methods for synthesising a mixed halide perovskite was conducted, namely FA₁₋ₐCSₐPb(I_{1-y}Br_{y})₃ wherein y and x are independently in the range 0.05-0.95. The multi-deposition (co-evaporation) method, not according to the invention, involved the deposition of the BX₂ metal halides by co-evaporating them together from a single chamber. The inorganic halide Csl was also co-evaporated with the metal halides. Thus, Pbl₂, PbBr₂ and Csl were all co-evaporated followed by deposition of FAI, demonstrated by the schematic of FIG. 5.

Meanwhile in the sequential deposition method according to the invention, the deposition of the metal halides is separated, as shown in FIG. 6 (i.e. the BX₂ metal halides are not co-evaporated). Instead, Pbl₂ and inorganic halide Csl are co-evaporated, followed by the sequential deposition of PbBr₂, further followed by the sequential deposition of FAI. This deposition process is referred to as “partial” sequential deposition since at least one step involves the co-evaporation of precursors, but it still falls within the invention as the BX₂ metal halides are not co-evaporated. Upon deposition of these respective layers, annealing in an oven was carried out at 80 to 200° C. for 20 minutes up to 5 hours to obtain the final perovskite layer.

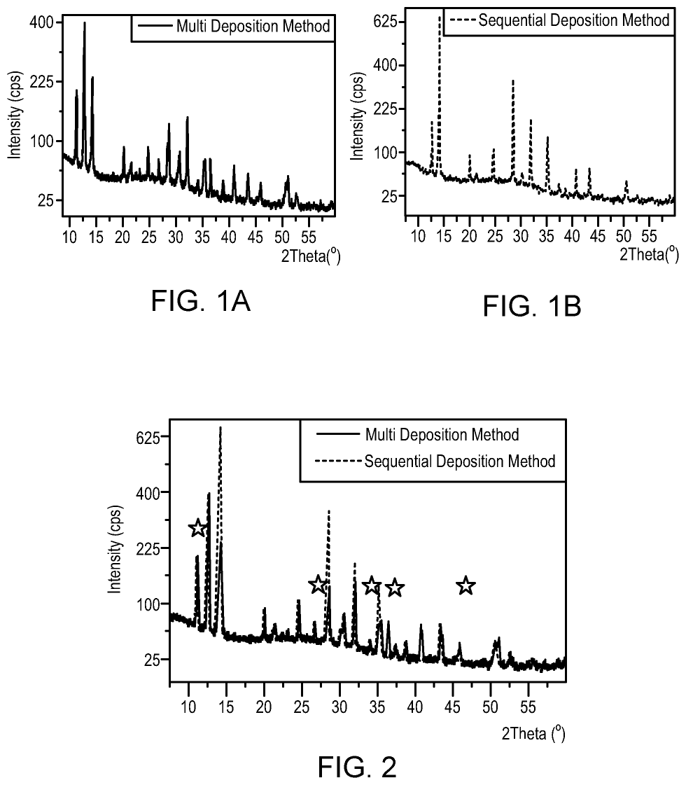

FIGS. 1A and 1B show the XRD for the FA₁₋ₐCsₐPb(I_{1-y}Br_{y})₃ perovskite produced via the multi-and sequential deposition method respectively. FIG. 2 shows a direct overlay of the XRD perovskite layer formed by each method. Evidently, the multi-deposition method shows more additional impurity phases (shown by the stars), namely the peak at ˜11° and the high intensity impurity peak at 12.5°, representing Pbl₂. In contrast, the sequential method, demonstrates a pure perovskite structure with comparably minimal residual metal halide (Pbl₂) left over. The large impurity phase in the multi-deposition pattern is evaluated to be from a combination of the metal halide layers which is formed when they are deposited together and is very difficult to convert when the halide salt, FAI, is then deposited. It is likely that these phases are a mixture of the inorganic components such as, Pbl₂, PbBr₂, and Csl. Three dominant phases are observed for the multi-deposition XRD; 1) a large amount of unreacted Pbl₂ is left in the XRD pattern (˜) 12.5°, 2) a small perovskite peak (˜) 14°, and 3) an additional phase, at ˜ 11°, which is likely a mixed metal halide phase, CsPb₂X₅ wherein X consists of mixed halides. Thus, a high-quality perovskite film can be formed via the sequential deposition method as shown in FIG. 2. The XRD pattern of the sequential deposition method shows 2 dominant phases; 1) a small amount of unreacted metal halide Pbl₂ and 2) a much stronger perovskite peak at ˜ 14°. This has several advantages, such as improving the processing efficiency and film quality. As the resultant perovskite will have fewer structural impurities, a stable and efficient device is more easily achieved. Thin layers of halide salts can be used, inevitably lowering production costs and minimising wastage.

### Example 2

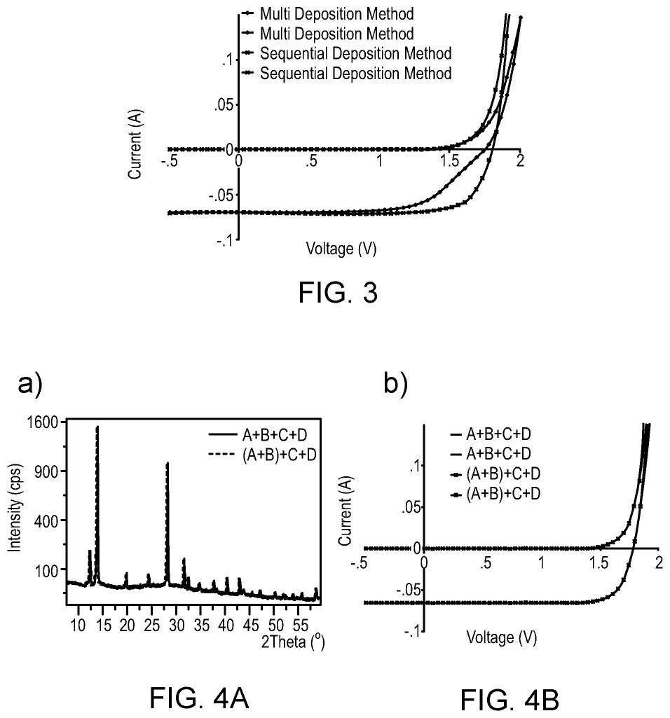

The photovoltaic device performance of a perovskite layer obtained by multi-deposition and sequential deposition was also investigated. Tandem photovoltaic devices were produced using the perovskite layer of Example 1 for the top sub-cell and a Si bottom sub-cell for each method. FIG. 3 shows the current-density (IV) curves resulting from the two deposition methods. It can clearly be seen that the devices produced by the sequential method demonstrate a much higher power conversion efficiency, with a higher V_{OC} and fill factor (FF). The reduced performance in the multi deposited device is exemplified by the S-shaped curve in the IV graph. This is indicative of a barrier forming at one of the interfaces and is likely due to the impurity phases produced in the perovskite films via this method.

### Example 3

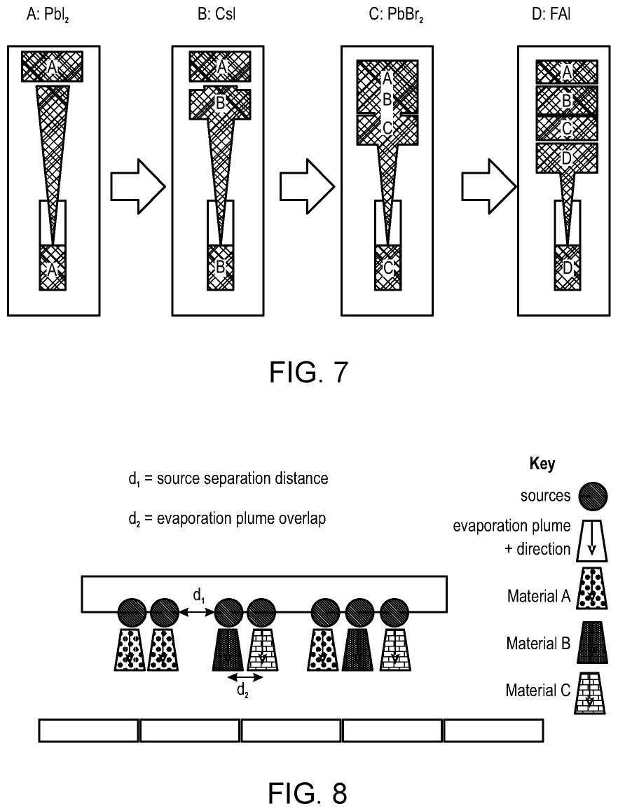

Similar results also arise for a fully sequential deposition system, where there is no co-evaporation of precursors (i.e. each precursor is deposited separately). Accordingly, a comparison of a fully sequential method and the partial sequential method outlined in Example 1 was also performed. For the fully sequential method, the perovskite film FA₁₋ₐCsₐPb(I_{1-y}Br_{y})₃ was made in the same way as the sequential method of Example 1, except all of the precursors were deposited separately, as illustrated by the scheme in FIG. 7 (A+B+C+D). The tandem perovskite device for the fully sequential method was also made according to the method in Example 2.

Evidently, the XRD patterns for the perovskite films according to both types of sequential method were mostly the same (FIG. 4A), indicating the fully sequential deposition method also eliminates impurities and achieves crystalline perovskites. The IV curves for the devices according to each deposition method were also reasonably identical (FIG. 4B), again highlighting the equivalent power efficiency when a fully sequential method is used to deposit the perovskite film. These results demonstrate that a partial or fully sequential method (both according to the invention) produces desirable device characteristics compared to the multi-deposition method (not according to the invention).

### Example 4

A further experiment was carried out according to the conditions and materials of the partial sequential deposition method of Example 1, but with an additional organic halide sequentially deposited to form an even more complex multi-component triple cation perovskite: FA_{1-a-b}CSₐGA_{b}Pb(I_{1-y}Br_{y})₃. A tandem perovskite device for this composition was also made, according to the method in Example 2.

In this Example, a layer of guanidinium halide (GAI) was deposited after the deposition of FAI. Large cations such as guanidinium can favourably enter the perovskite lattice and enhance the overall stability of perovskite film, such as towards thermal or moisture degradation.

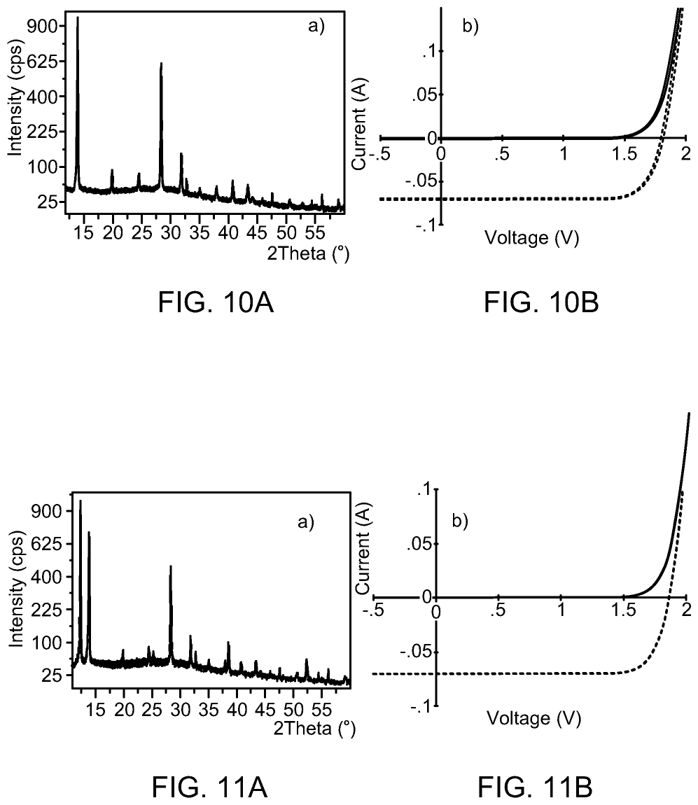

The XRD pattern in FIG. 10A shows that this partial sequential method produced a crystalline and phase pure FA_{1-a-b}CSₐGA_{b}Pb(I_{1-y}Br_{y})₃ film. Furthermore, the IV curve in FIG. 10B also demonstrates that devices with complex perovskite composition comprising large cations still demonstrate a higher power conversion efficiency when produced via the partial sequential method according to the invention, compared to the multi-deposition method described in Example 1.

### Example 5

A further experiment was carried out according to the conditions and materials of the partial sequential deposition method of Example 1, but with an additional metal halide sequentially deposited to form an even more complex multi-component triple halide perovskite: FA_{1-a-b}CSₐGA_{b}Pb(I_{1-y-z}Br_{y}Cl_{z})₃. A tandem perovskite device for this composition was also made, according to the method in Example 2.

In this Example, a layer of lead chloride (PbCl₂) was deposited after the deposition of PbBr₂, but before the deposition of the FAI layer.

The XRD pattern in FIG. 11A shows that the partial sequential method produced a crystalline and phase pure FA₁₋ₐCSₐPb(I_{1-y-z}Br_{y}Cl_{z})₃ film. Furthermore, the IV curve in FIG. 11B also demonstrates that devices with complex perovskite compositions still demonstrate a higher power conversion efficiency when produced via the partial sequential method, compared to the multi-deposition method described in Example 1. This Example further shows that sequentially depositing the metal halides surprisingly maintains a phase pure and crystalline perovskite, despite the numerous halide components.

### Example 6

A further experiment was carried out according to the conditions and materials of the partial sequential deposition method of Example 1, but with the deposition order changed. Thus, the same perovskite composition, FA₁₋ₐCsₐPb(I_{1-y}Br_{y})₃, was synthesised. A tandem perovskite device for this composition was also made, according to the method in Example 2.

In this Example, the Pbl₂ and Csl were co-evaporated together first (instead of PbBr₂ and Csl as in Example 1). Subsequently FAI was deposited, followed by PbBr₂.

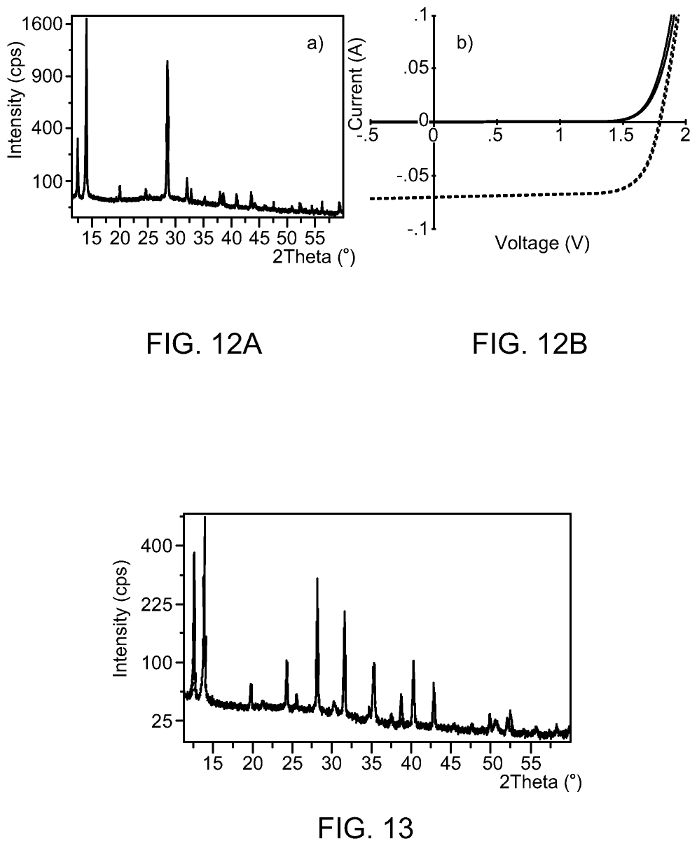

The XRD pattern in FIG. 12A shows that the partial sequential method produced a crystalline and phase pure FA₁₋ₐCsₐPb(I_{1-y}Br_{y})₃ film. Furthermore, the IV curve in FIG. 12B also demonstrates that changing the order of deposition and the identity of the metal halide which is co-evaporated with the inorganic halide, does not affect the device characteristics. Indeed, a higher power conversion efficiency was achieved compared to the multi-deposition method described in Example 1. Hence, this Example shows the adaptability of the sequential method to different ordering and different combinations of precursors for co-evaporation (provided the metal halides are not co-evaporated).

### Example 7

A further experiment was carried out wherein a tin halide was deposited as one of the metal halides instead of lead halide to form a complex multi-component mixed metal perovskite.

In this Example, Snl₂ was first deposited, followed by the sequential deposition of PbCl₂ and FAI, respectively. Hence, a fully sequential deposition method was employed. As in Example 1, upon deposition of these respective layers, annealing in an oven was carried out at 80 to 200° C. for 20 minutes for up to 5 hours to obtain the final perovskite layer.

The XRD pattern in FIG. 13 shows that the fully sequential method produced a crystalline and phase pure FA₁₋ₐCsₐSn₁₋ₓPbₓ(I_{1-y}Cl_{y})₃ film. Hence, this example shows that the sequential method can be used to sequentially deposit two or more metal halides wherein the metal and halide anions both differ, while maintaining a crystalline composition substantially free of impurities.

### Example 8

A further comparative multi-deposition experiment (not according to the invention) was carried out wherein two metal halides were co-evaporated and hence deposited together. This method was similar to the multi-deposition method of Example 1, but without the inclusion of the Csl precursor.

In this Example, Pbl₂ and PbBr₂ were co-evaporated and then FAI was subsequently deposited to form the perovskite film FAPb(I_{1-y}Br_{y})₃.

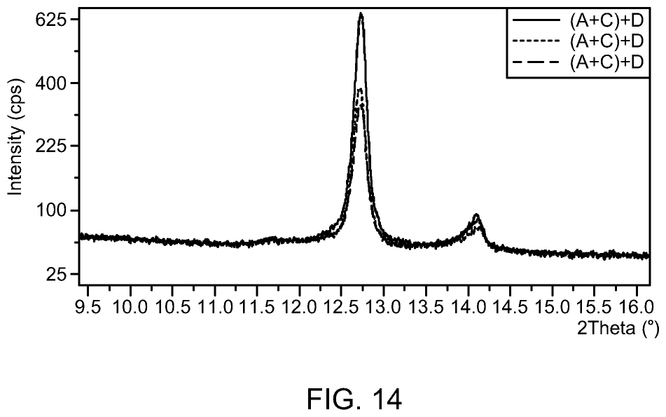

The XRD FIG. 14 clearly shows that perovskite formation has significantly been inhibited by mixing the Pbl₂ and PbBr₂ components since the most intense peak is the impurity Pbl₂ (12°) peak. It can further be seen that the characteristic perovskite peak (˜14° is significantly reduced. Clearly, separating the deposition of metal halides according to the invention favours perovskite formation with minimal impurities.

In conclusion, it has been demonstrated that a sequential deposition process (partial or full) to synthesise crystalline perovskite films can be utilized to produce efficient photovoltaic devices. The claimed method also incurs many advantages in terms of process control of the individual layers/components and the capability to adopt a simple, effective and fully in-line production process, which is essential for the industrialization of this technology. As shown by the above Examples, the sequential deposition method according to the invention is capable of consistently producing high quality crystalline films of complex perovskites, spanning compositions with several organic and inorganic A cations, mixed metal B cations, and multiple halide anions. The process is highly versatile, not requiring any specific ordering so long as the metal halide depositions are separated.

1. A method for producing a perovskite material which comprises:
i. depositing a first metal halide precursor; and
ii. depositing a second metal halide precursor, wherein a halide component in the second metal halide precursor is different from that of the first metal halide precursor and the first and second metal halide precursors are deposited separately; and at least one of steps iii and iv:
iii. depositing an inorganic halide precursor; and/or
iv. depositing a first organic halide precursor;
to form the perovskite material which comprises a mixed halide; wherein steps i. and ii. are carried out by a physical vapour deposition and step iii., if present, is carried out by a physical vapour deposition.

2. The method according to claim 1 further comprising a step v. of deposition of a second organic halide precursor which is different from the first organic halide precursor.

3. The method according to claim 2 further comprising a step vi. of deposition of a third organic halide precursor which is different from the first and second organic halide precursors.

4. The method according to claim 1 which further comprises a final annealing step.

5. The method according to claim 2 wherein steps iv., if present, and v., if present, are carried out by physical vapour deposition, preferably wherein all steps are carried out by physical vapour deposition.

6. The method according to claim 1 for producing a thin film of perovskite material.

7. The method according to claim 1, wherein three or more precursors are sequentially vapour deposited on a substrate.

8. The method according to claim 1 wherein step iii. is present and the deposition of the first metal halide precursor and the inorganic halide precursor is done together in a co-evaporation step.

9. The method according to claim 1 wherein the steps are carried out in any order.

10. The method according to any preceding claim 1 wherein the perovskite material comprises two or more different monovalent cations.

11. The method according to any preceding claim 1, wherein the first and second metal halide precursors in steps i. and ii. independently comprise a divalent cation.

12. The method according to claim 1, wherein the first metal halide precursor has formula BX₂ and wherein the second metal halide precursor has formula BX′₂, wherein each B is the same or different and is selected from a metal cation, and X and X′ are different and are each independently selected from halide anions.

13. The method according to claim 1, wherein the first metal halide precursor has formula BX and wherein the second metal halide precursor has formula BX′3, or vice versa, wherein each B is the same or different and is a metal cation, and X and X′ are different and are independently selected from halide anions.

14. The method according to claim 1, wherein the inorganic halide precursor in step iii. has formula AX, wherein A comprises a monovalent metal cation and X is a halide anion.

15. The method according to claim 1, wherein the inorganic halide precursor in step iii. is selected from bromides or iodides of Cs⁺.

16. The method according to claim 1 wherein the first, second and third organic halide precursors, where present, have formulae A′X, A″X and A″′X respectively, wherein A′, A″ and A′″ are, independently, selected from monovalent organic cations.

17. The method according to claim 16 wherein the first organic halide precursor has formula A′X wherein A′ is selected from MA, FA, and EA.

18. The method according to claim 16 wherein the second organic halide precursor has formula A″X where A″ is selected from MA, FA, GA, EA, BzA, BA, DMA, Im, PEA, and Ac.

19. The method according to claim 16 wherein the third organic halide precursor has formula A′″X where A″′ is selected from MA, FA, GA, EA, BZA, BA, DMA, Im, PEA, and Ac.

20. The method according to claim 1, wherein the halide components of the first and second metal halide precursors in steps i. and ii. are independently selected from iodides, chlorides, and bromides.

21. The method according to claim 1, wherein the second metal halide precursor has a different metal component to the first metal halide precursor.

22. The method according to claim 1, wherein the perovskite material has formula (I):
AₐA′_{b}A″_{c}A″′ₐBₓB′₁₋ₓ(X_{y}X′_{1-y})₃,
wherein;
A is a monovalent inorganic cation;
A′ is a first monovalent organic cation;
A″ is a second monovalent organic cation;
A″′ is a third monovalent organic cation;
wherein all A cations A, A′, A″ and A′″ are different from each other and;
B is a divalent metal cation;
B′ is a different divalent metal cation to B;
X is a halide anion;
and X′ is a different halide anion to X;
$$0 \leq a < 1 \\ 0 \leq b < 1 \\ 0 \leq c < 1 \\ 0 \leq d < 1 \\ a + b + c + d = 1 \\ 0 \leq x < 1 \\ and 0 < y < 1$$

23. The method according to any preceding claim 1, wherein the process is a layer-by-layer deposition carried out one or more times in a linear sequence.

24. The method according to any preceding claim 1, wherein the process is carried out one or more times to obtain a desired thickness of the perovskite in the range 50 to 2000 nm.

25. A method of making a multi-junction photovoltaic device comprising two or more sub-cells, a first sub-cell comprising a first photovoltaic device, wherein the photovoltaic device comprises a photoactive region comprising a perovskite material prepared according to the method of claim 1; and a further sub-cell comprising a further photovoltaic device, wherein the further photovoltaic device comprises a photoactive region.

26. A perovskite material obtainable by the method according to claim 1.

27. A semiconductor device having a photoactive region comprising a perovskite material according to claim 26.

28. The method semiconductor device according to claim 27, wherein the semiconductor device is a photovoltaic device having a photoactive region.

29. The method photovoltaic device according to claim 28 wherein the photoactive region comprises a thin film of the perovskite material.

30. A multi-junction photovoltaic device comprising two or more sub-cells, the first sub-cell comprising a first photovoltaic device, wherein the photovoltaic device comprises a photoactive region comprising a perovskite material prepared according to the method of claim 1; and a further sub-cell comprising a further photovoltaic device, wherein the photovoltaic device comprises a photoactive region.

31. The method according to claim 5 wherein all steps are carried out by a physical vapour deposition.

32. The method according to claim 11, wherein the first and second metal halide precursors in steps i. and ii. are independently selected from Pb²⁺ and Sn²⁺.

33. The method of making a multi-junction photovoltaic device according to claim 25 wherein the photoactive region of the further photovoltaic device comprises a perovskite material prepared according to a method comprising:
i. depositing a first metal halide precursor; and
ii. depositing a second metal halide precursor, wherein a halide component in the second metal halide precursor is different from that of the first metal halide precursor and the first and second metal halide precursors are deposited separately; and at least one of steps iii and iv:
iii. depositing an inorganic halide precursor; and/or
iv. depositing a first organic halide precursor;
to form the perovskite material which comprises a mixed halide; wherein steps i. and ii. are carried out by a physical vapour deposition and step iii., if present, is carried out by a physical vapour deposition.

34. The multi-junction photovoltaic device according to claim 30 wherein the photoactive region of the further photovoltaic device comprises a perovskite material prepared according to a method comprising:
i. depositing a first metal halide precursor; and
ii. depositing a second metal halide precursor, wherein a halide component in the second metal halide precursor is different from that of the first metal halide precursor and the first and second metal halide precursors are deposited separately; and at least one of steps iii and iv:
iii. depositing an inorganic halide precursor; and/or
iv. depositing a first organic halide precursor;
to form the perovskite material which comprises a mixed halide; wherein steps i. and ii. are carried out by a physical vapour deposition and step iii., if present, is carried out by a physical vapour deposition.
